(19) United States
(12) Patent Application Publication
(10) Pub. No.: US 2011/0281219 A9
(43) Pub. Date: Nov. 17, 2011

(54) Apparatus and Method for Thermally Developing Flexographic Printing Elements

(76) Inventor: Ryan W. Vest, Cumming, GA (US)

(21) Appl. No.: 12/267,642

(22) Filed: Nov. 10, 2008

Related U.S. Application Data
(63) Continuation-in-part of application No. 11/249,864, filed on Oct. 13, 2005, now abandoned.

(51) Int. Cl. G03F 7/00

(52) U.S. Cl. 430/306

(57) ABSTRACT

A method for developing an imaged and exposed photopolymer printing element is disclosed where the printing element is heated to a temperature sufficient to selectively melt or soften the non-cured portions of the photopolymer such that the softened or melted non-cured photopolymer is removable from the printing element by contacting the heated printing element with a blotter. The image of the removed non-cured photopolymer is obscured by using a darkly colored blotter thereby increasing the security of the printing operation.

### FIELD OF THE INVENTION

The present invention is directed to a method and an apparatus for thermally developing flexographic printing elements, including printing plates and printing sleeves.

### BACKGROUND OF THE INVENTION

Flexography is a method of printing that is commonly used for high-volume runs. Flexography is employed for printing on a variety of substrates such as paper, paperboard stock, corrugated board, films, foils and laminates. Newspapers and grocery bags are prominent examples. Coarse surfaces and stretched films can be economically printed only by means of flexography. Flexographic printing plates are relief plates with image elements raised above open areas. Such plates offer a number of advantages to the printer, based chiefly on their durability and the ease with which they can be made.

Although photopolymer printing elements are typically used in “flat” sheet form, there are particular applications and advantages to using the printing element in a continuous cylindrical form, as a continuous in-the-round (CITR) photopolymer sleeve. CITR photopolymer sleeves add the benefits of digital imaging, accurate registration, fast mounting, and no plate lift to the flexographic printing process. CITR sleeves have applications in the flexographic printing of continuous designs such as in wallpaper, decoration and gift-wrapping paper, and other continuous designs such as tablecloths, etc. CITR sleeves enable flexographic printing to be more competitive with gravure and offset on print quality.

A typical flexographic printing plate as delivered by its manufacturer, is a multilayered article made of, in order, a backing or support layer, one or more unexposed photocurable layers, a protective layer or slip film, and a cover sheet. A typical CITR photopolymer sleeve generally comprises a sleeve carrier (support layer) and at least one unexposed photocurable layer on top of the support layer.

It is highly desirable in the flexographic prepress printing industry to eliminate the need for chemical processing of printing elements in developing relief images, in order to go from plate to press more quickly. Processes have been developed whereby photopolymer printing plates are prepared using heat and the differential melting temperature between cured and uncured photopolymer is used to develop the latent image. The basic parameters of this process are known, as described in U.S. Pat. Nos. 5,279,697, 5,175,072 and 3,264,103, in published U.S. patent publication Nos. US 2003/0180655, and U.S. 2003/0211423, and in WO 01/88615, WO 01/18604, and EP 1239329, the teachings of each of which are incorporated herein by reference in their entirety. These processes allow for the elimination of development solvents and the lengthy plate drying times needed to remove the solvent. The speed and efficiency of the process allow for use of the process in the manufacture of flexographic plates for printing newspapers and other publications where quick turnaround times and high productivity are important.

The photopolymer layer allows for the creation of the desired image and provides a printing surface. The photopolymers used generally contain binders, monomers, photoinitiators, and other performance additives. Photopolymer compositions useful in the practice of this invention include those described in U.S. patent application Ser. No. 10/353,446 filed Jan. 29, 2003, the teachings of which are incorporated herein by reference in their entirety. Various photopolymers such as those based on polystyrene-isoprene-styrene, polystyrene-butadiene-styrene, polyurethanes and/or thiolenes as binders are useful. Preferable binders are polystyrene-isoprene-styrene, and polystyrene-butadiene-styrene, especially block co-polymers of the foregoing.

The composition of the photopolymer should be such that there exists a substantial difference in the melt temperature between the cured and uncured polymer. It is precisely this difference that allows the creation of an image in the photopolymer when heated. The uncured photopolymer (i.e., the portions of the photopolymer not contacted with actinic radiation) will melt or substantially soften while the cured photopolymer will remain solid and intact at the temperature chosen. Thus the difference in melt temperature allows the uncured photopolymer to be selectively removed thereby creating an image.

The printing element is selectively exposed to actinic radiation, which is traditionally accomplished in one of three related ways. In the first alternative, a photographic negative with transparent areas and substantially opaque areas is used to selectively block the transmission of actinic radiation to the printing plate element. In the second alternative, the photopolymer layer is coated with an actinic radiation (substantially) opaque layer, which is also sensitive to laser ablation. A laser is then used to ablate selected areas of the actinic radiation opaque layer creating an in situ negative, and the printing element is then flood exposed through the in situ negative. In the third alternative, a focused beam of actinic radiation is used to selectively expose the photopolymer. Any of these alternative methods produces an acceptable result, with the criteria being the ability to selectively expose the photopolymer to actinic radiation thereby selectively curing portions of the photopolymer.

Once the photopolymer layer of the printing element has been selectively exposed to actinic radiation, it can then be developed using heat. As such, the printing element is generally heated to at least about 70° C. The exact temperature will depend upon the properties of the particular photopolymer being used. However, two primary factors should be considered in determining the development temperature:
1. The development temperature is preferably set between the melt temperature of the uncured photopolymer on the low end and the melt temperature of the cured photopolymer on the upper end. This will allow selective removal of the photopolymer, thereby creating the image.
2. The higher the development temperature, the quicker the process time will be. However, the development temperature should not be so high as to exceed the melt temperature of the cured photopolymer or so high that it will degrade the cured photopolymer. The temperature should be sufficient to melt or substantially soften the uncured photopolymer thereby allowing it to be removed.

Once the printing element has been heated, uncured photopolymer can be melted or removed. In most instances, the heated printing element is contacted with a material that will absorb or otherwise remove the softened or melted uncured photopolymer. This removal process is generally referred to as “blotting”. Blotting is typically accomplished using an absorbent fabric. Either woven or non-woven fabric is used and the fabric can be polymer based or paper, so long as the fabric can withstand the operating temperatures involved. Generally the blotter fabric is a white non-woven fabric such as Cerex®. Use of these white materials causes a disadvantage in that the image of the printing plate can be discovered from the fabric. This causes a security concern in that, when the fabric is disposed of, the printed image can be seen. In most instances, blotting is accomplished using rollers to bring the material and the heated printing plate element into contact.

U.S. Pat. No. 5,175,072 to Martens, the subject matter of which is herein incorporated by reference in its entirety, describes the removal of uncured portions of the photopolymer by using an absorbent sheet material. The uncured photopolymer layer is heated by conduction, convection, or other heating method to a temperature sufficient to effect melting. By maintaining more or less intimate contact of the absorbent sheet material with the photocurable layer, a transfer of the uncured photopolymer from the photopolymer layer to the absorbent sheet material takes place. While still in the heated condition, the absorbent sheet material is separated from the cured photopolymer layer in contact with the support layer to reveal the relief structure. After cooling, the resulting flexographic printing plate can be mounted on a printing plate cylinder.

Upon completion of the blotting process, the printing plate element is preferably post-exposed to further actinic radiation in the same machine, cooled and then ready for use.

As such, there remains a need in the art for an improved blotting system that can increase security by hiding or obscuring the image left on the blotter material. Thus, it is an object of this invention to disclose an improved blotter material which will obscure the image left on the blotter material thereby increasing the overall security of the process.

### SUMMARY OF THE INVENTION

The present invention comprises an improved thermal development method to remove uncured photopolymer from the imaged surface of a flexographic printing element.

In a preferred embodiment, the method comprises:

(i) supporting, and preferably cycling or rotating, a flexographic printing element which has been previously selectively exposed to actionic radiation such that portions of the printing elements comprise cured photopolymer and portions comprise uncured photopolymer;

(ii) thermally developing said the flexographic printing element, by:
a) softening or melting uncured photopolymer on of the flexographic printing element by exposing the flexographic printing element to heat;
b) contacting the heated flexographic printing element with a blotter material such that the uncured photopolymer is removed from the flexographic printing element;

wherein the blotter is colored in such a manner that the image created on the blotter by the uncured photopolymer is not discernable by the unaided human eye.

In one embodiment, the means for softening or melting non-crosslinked photopolymer on the imaged and exposed surface of the flexographic printing element comprises heating at least one roll that is used to contact the blotter with the imaged surface of the flexographic printing element. In another embodiment of the invention, the means for softening or melting non-crosslinked photopolymer on the imaged and exposed surface of the flexographic printing element comprises positioning a heater adjacent to the imaged and exposed surface of the flexographic printing element. The heated roll and external heater can also be used together.

The invention also comprises a method of thermal development of a flexographic printing element comprising the steps of:

a) supporting and rotating the flexographic printing element;

b) optionally, but preferably, exposing an imaged surface of the flexographic printing element to one or more sources of actinic radiation;

c) melting or softening non-crosslinked polymer on the imaged surface of the flexographic printing element using heat;

d) causing contact between the imaged surface of the flexographic printing element and a blotter using at least one roll; and

e) rotating the at least one roll against at least a portion of the imaged surface of the flexographic printing element to cause the blotter to remove non-crosslinked photopolymer from the imaged and exposed surface of the flexographic printing element;

wherein the blotter is colored in such a manner that the image created on the blotter by the uncured photopolymer is not discernable by the unaided human eye.

### BRIEF DESCRIPTION OF THE DRAWINGS

FIG. 1 depicts one embodiment of the thermal development apparatus useful in practicing the instant invention.

FIG. 2 depicts a different view of the thermal development apparatus useful in practicing one embodiment of the invention and shows the motion of the heated roll traversing the length of the cylindrical printing element.

FIG. 3 depicts another embodiment of the thermal development apparatus useful in practicing the instant invention wherein opposing heads are used to improve imaging speed and eliminate roll bending and machine stiffness design problems.

FIG. 4 depicts an embodiment of the invention wherein the exposing and developing steps are accomplished at the same time on the same apparatus.

FIG. 5 depicts another embodiment of the invention wherein the combined exposing and developing apparatus further comprises a device to de-tack and post cure the printing element.

### DETAILED DESCRIPTION OF THE PREFERRED EMBODIMENTS OF THE INVENTION

The present invention relates to a method of using the apparatus to remove non-crosslinked polymer from an imaged surface of a relief image printing element during a process for manufacturing the relief image printing element.

A flexographic printing element is produced from a photocurable printing blank by imaging the photocurable printing blank to produce a relief image on the surface of the printing element. This is generally accomplished by selectively exposing the photocurable material to actinic radiation, which exposure acts to harden or crosslink the photocurable material in the irradiated areas.

The photocurable printing blank contains one or more layers of an uncured photocurable material on a suitable backing layer. The photocurable printing blank can be in the form of a continuous (seamless) sleeve or as a flat, planar plate that is mounted on a carrier sleeve. The plate can be held onto the carrier sleeve using any suitable means, including vacuum, adhesive, and/or mechanical clamps.

The printing element is selectively exposed to actinic radiation in one of three related ways. In the first alternative, a photographic negative with transparent areas and substantially opaque areas is used to selectively block the transmission of actinic radiation to the printing plate element. In the second alternative, the photopolymer layer is coated with an actinic radiation (substantially) opaque layer that is sensitive to laser ablation. A laser is then used to ablate selected areas of the actinic radiation opaque layer creating an in situ negative. In the third alternative, a focused beam of actinic radiation is used to selectively expose the photopolymer. Any of these alternative methods is acceptable, with the criteria being the ability to selectively expose the photopolymer to actinic radiation thereby selectively curing portions of the photopolymer.

In a preferred embodiment, the printing element comprises a photopolymer layer that is coated with an actinic radiation (substantially) opaque layer, which typically comprises carbon black, and which is sensitive to laser ablation. A laser, which is preferably an infrared laser, is then used to ablate selected areas of the actinic radiation opaque layer creating an in situ negative. This technique is well-known in the art, and is described for example in U.S. Pat. Nos. 5,262,275 and 6,238,837 to Fan, and in U.S. Pat. No. 5,925,500 to Yang et al., the subject matter of each of which is herein incorporated by reference in their entirety.

The selected areas of the photopolymer layer revealed during laser ablation are then exposed to actinic radiation to crosslink and cure the portions of the photopolymer layer that are not covered by the in situ negative. The type of radiation used is dependent on the type of photoinitiator in the photopolymerizable layer. The radiation-opaque material in the infrared sensitive layer which remains on top of the photopolymerizable layer prevents the material beneath from being exposed to the radiation and thus those areas covered by the radiation-opaque material do not polymerize. The areas not covered by the radiation-opaque material are exposed to actinic radiation and polymerize and thus crosslink and cure. Any conventional sources of actinic radiation can be used for this exposure step. Examples of suitable visible or UV sources include carbon arcs, mercury-vapor arcs, fluorescent lamps, electron flash units, electron beam units and photographic flood lamps.

Next, the photopolymer layer of the printing element is developed to remove uncured (i.e., non-crosslinked) portions of the photopolymer, without disturbing the cured portions of the photopolymer layer, to produce the relief image.

The apparatus for thermally developing in printing element typically comprises:

(i) means to support, and preferably cycle or rotate, a flexographic printing element;

(ii) optionally, but preferably, means for exposing an imaged surface of the flexographic printing element to actinic radiation; and

(iii) means for thermally developing said imaged and exposed surfaces of the flexographic printing element, wherein the thermally developing means typically comprises:
a) means for softening or melting non-crosslinked photopolymer on the imaged and exposed surface of the flexographic printing element using the application of heat to the flexographic printing element;
b) at least one roll that is capable of bringing blotter material into contact with the imaged surface of the flexographic printing element and capable of moving over at least a portion of the imaged surface of the flexographic printing element to remove the softened or melted non-crosslinked photopolymer on the imaged and exposed surface of the flexographic printing element; and
c) means for maintaining contact between the at least one roll and the imaged and exposed surface of the flexographic printing element

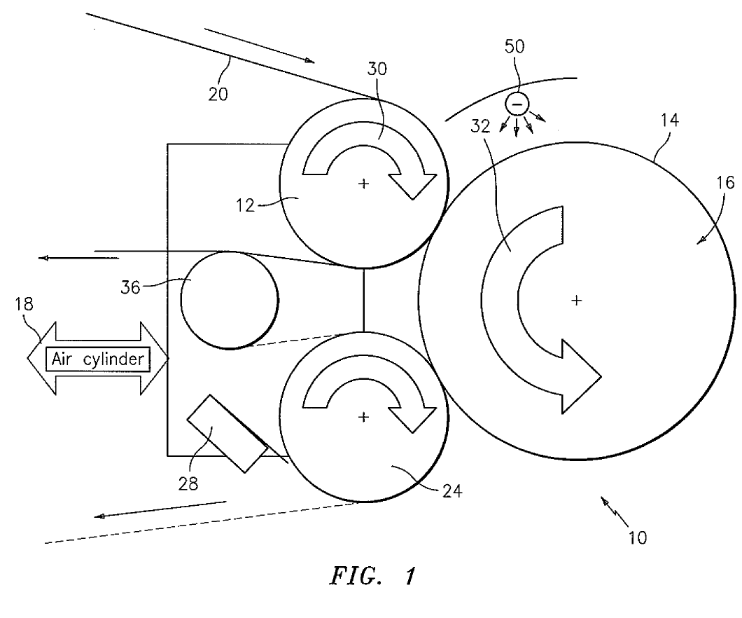

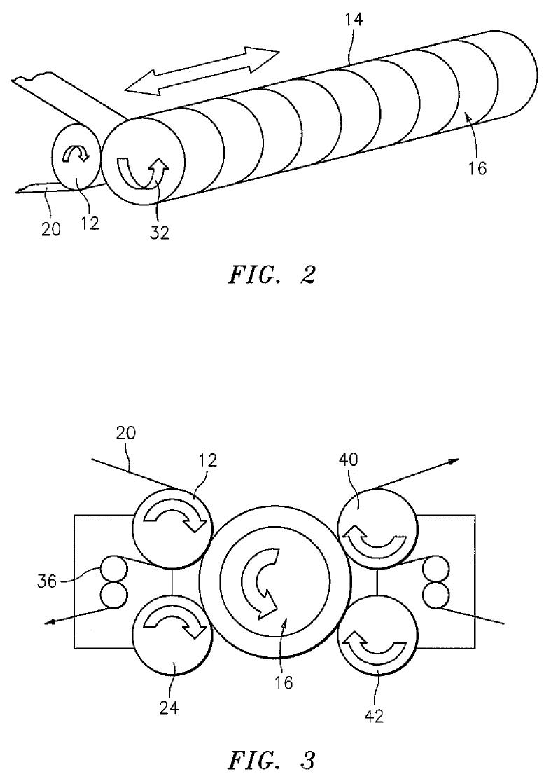

As depicted in FIG. 1, the thermal developing apparatus (10) generally comprises at least one roll (12) that is contactable with an imaged surface (14) of a flexographic printing element (16) and a means (18) for maintaining contact between the at least one roll (12) and the imaged surface (14) of the flexographic printing element (16). In one embodiment, the at least one roll (12) is heated and is moved over at least a portion of the imaged surface (14) of the flexographic printing element (16), and non-crosslinked polymer on the imaged surface (14) of the flexographic printing element (16) is melted and removed by the at least one heatable roll (12). In another embodiment a heating source (50) is positioned prior to the roll (12) to soften or melt non-crosslinked polymer on the imaged and exposed surface of the flexographic printing element for subsequent removal by the roll (12). The heating source (50) may also be used in conjunction with the heated roll (12) to at least partially soften or melt non-crosslinked polymer on the imaged surface of the flexographic printing element.

The thermal developing apparatus may comprise two rolls (12) and (24) that are opposably positionable adjacent and apart from each other and are each maintainable in contact with the imaged surface (14) of the flexographic printing element (16). When the two rolls (12) and (24) are contacted with the imaged surface (14) of the flexographic printing element (16), the two rolls (12) and (24) are self-centering against the imaged surface (14) of the flexographic printing element (16).

The heating source (50) is typically an infrared heater or hot air heater, although other heating sources could also be used in the practice of the invention and would be known to those skilled in the art. In a preferred embodiment, the heating source is an infrared heater. In the alternative, or in addition, the at least one roll can be a heated roller with a heating source contained within the roll.

The means (18) for maintaining contact between the at least one roll (12) and the imaged surface (14) of the flexographic printing element (16) typically comprises an air cylinder or a hydraulic cylinder that acts to force the at least one roll (12) against the imaged surface (14) of the flexographic printing element (16). Other means for maintaining the contact between the at least one roll (12) and the flexographic printing element (16) would also be known to one skilled in the art.

Although the flexographic printing element (16) is depicted as being a cylindrical flexographic printing element, i.e., a printing sleeve, as discussed above, the invention is not limited to cylindrical flexographic printing elements and would also be usable for removing non-crosslinked polymer from the imaged surface of a flat flexographic printing element. The flat flexographic printing element may be used as a printing plate or may be wrapped around a cylindrical shaft and used as a cylindrical printing element.

In a preferred embodiment, the thermal developing apparatus comprises a blotting material (20) positioned on at least a portion of the at least one roll (12). Thus, when the at least one roll (12) is heated and is contacted with the imaged surface (14) of the flexographic printing element (16), non-crosslinked polymer on the imaged surface (14) of the flexographic printing element (16) is melted by the heated roll (12) and is removed by the blotting material (20). Alternately, the heating source (50) melts or softens the non-crosslinked polymer and the blotting material (20) positioned on at least a portion of the at least one roll removes the melted or softened polymer.

The blotting material (20) is typically looped under and around at least the portion of the at least one roll (12) that contacts the imaged surface (14) of the flexographic printing element (16). The blotting material (20) is continuously supplied to the at least one roll (12) from a remote source (not shown) of the blotting material (20). The thermal developing apparatus further comprises a rewind device (not shown) to carry away the blotting material (20) that contains the removed non-crosslinked polymer.

The blotting material preferably comprises paper or woven or non-woven fabrics. Blotting materials that are usable include screen mesh and absorbent fabrics, including polymer-based and non-polymer-based fabrics. For the purposes of this invention, it is important that the blotting material be a dark color. Generally the darker the better. Typically black, brown, blue or green will suffice with black being preferred. The blotter should be dark enough that the image created by the removed uncured photopolymer on the blotter cannot be seen with the unaided human eye. Generally the blotter comprises a non-woven fabric comprised of either polyester or nylon, with nylon being preferred. Basis weight of the fabric can range from 1 to 2 ounces per square yard. The fabric may comprise a single or multiple layers. One suitable fabric is CEREXA® if colored to a dark colored form since CEREX® is commercially supplied in white. Since the blotter is discarded as trash after use, this is advantageous because it increases security by hampering the effort of anyone seeing the image of what was printed in the discarded blotter.

In an alternate embodiment, the thermal developing apparatus comprises a doctor blade (28) that is positionable adjacent to the at least one roll (12) or (24), which is shown positioned adjacent to the second roll (24). When the at least one roll (24) removes non-crosslinked polymer from the imaged surface (14) of the flexographic printing element (16), the doctor blade (28) wipes the non-crosslinked polymer from the surface of the at least one roll (24).

The thermal developing apparatus removes non-crosslinked polymer from the imaged surface (14) of the flexographic printing element by rotating the at least one roll (12) over at least a portion of the imaged surface (14) of the flexographic printing element (16) such that the blotter removes the uncured photopolymer. Preferably, the at least one roll (12) rotates in a first direction (30) and the cylindrical flexographic printing element (16) rotates in an opposite direction (32) from the at least one roll (12).

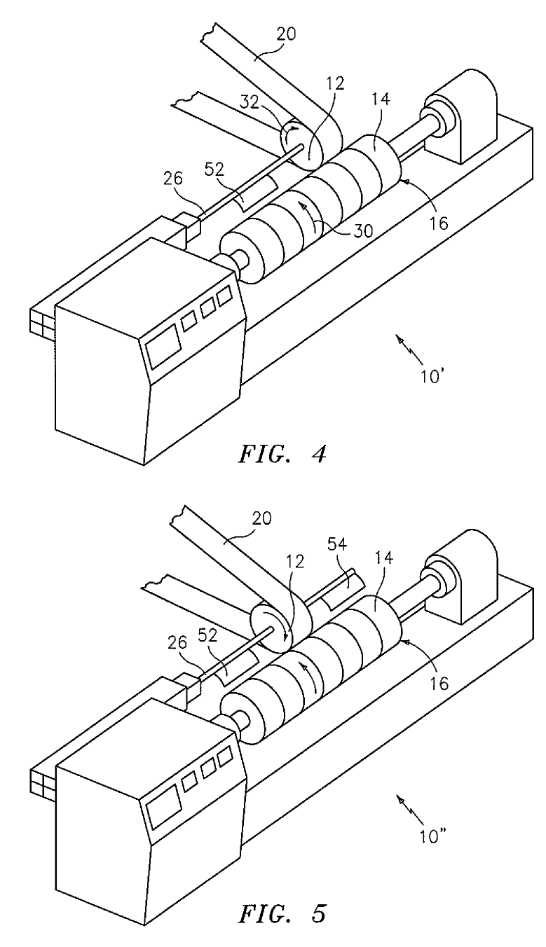

The thermal developing apparatus may also comprise means (26) (shown in FIG. 4) for allowing the at least one roll to traverse along the length of the cylindrical flexographic printing element, and such means typically comprise one or more carriages. The advantage to this design feature is that movement of the roll across the surface of the printing element allows the improved thermal developing apparatus of the invention to accommodate printing elements of various lengths and diameters. In this case, the at least one roll rotates along the length or around the circumference of the printing element and also moves in a direction parallel to the axis of rotation along the width of the printing element.

The blotting material (20) may be continuously fed to the two rolls (12) and (24) by looping the blotting material (20) under and around at least the portion of the first roll (12) that is contactable with the imaged surface (14) of the flexographic printing element (16), looping the blotting material (20) around one or more track rolls (36) positioned between the two rolls (12) and (24), and then looping the blotting material (20) under and around at least the portion of the second roll (24) that is contactable with the imaged surface (14) of the flexographic printing element (16).

As shown in FIG. 3, the thermal developing apparatus may further comprise one or more additional rolls (40) and (42) that are positionable in an opposing position on an opposite side of the cylindrical flexographic printing element (16). The one or more additional rolls (40) and (42) are maintainable in contact with at least a portion of the imaged surface (14) of the flexographic printing element (16). When the one or more additional rolls (40) and (42) are contacted with the imaged surface (14) of the flexographic printing element (16), removal of resin from the imaged surface (14) of the flexographic printing element (16) as well as the imaging speed can be increased. Use of the two additional rolls (40) and (42) may also eliminate roll bending and machine stiffness design problems, which can cause uneven floors in large flat plate machines. Also, since the high forces required to push the blotter into the resin oppose each other, the improved design features of the invention allow for the use of much lighter materials (i.e., fiberglass instead of steel support shafts) to support the printing sleeve while it is being processed.

As shown in FIG. 4, the apparatus may include means for both exposing and thermally developing the flexographic printing element.

The exposing and thermal development apparatus (10) depicted in FIG. 4 typically comprises one or more sources of actinic radiation (52) mounted on a carriage (26) that can traverse the length of the flexographic printing element (16). The one or more sources of actinic radiation (52) typically comprise one or more UV light sources that are capable of selectively exposing and curing the imaged surface (14) of the flexographic printing element (16).

During operation, the carriage (26) traverses the one or more sources of actinic radiation (52) over the length of the imaged surface (14) of the flexographic printing element (16) to cure the flexographic printing element (16). While the carriage (26) traverses the length of the imaged surface (14) of the flexographic printing element (16), the flexographic printing element (16) is continuously rotated in a first direction (30) so that the entire imaged surface of the flexographic printing element (16) is exposed to cure the imaged surface (14) of the flexographic printing element (16).

The at least one roll (12) may be mounted on the same carriage (26) as the one or more sources of actinic radiation (52), or may be mounted on a separate carriage (not shown) from the one or more sources of actinic radiation (52). As shown in FIG. 1, the apparatus also contains means (18) for maintaining contact between the at least one roll (12) and the imaged surface (14) of the flexographic printing element (16).

The at least one roll (12) is moved over at least a portion of the imaged surface (14) of the flexographic printing element (16) that has previously been traversed by the one or more sources of actinic radiation (52) to remove non-crosslinked polymer on the imaged surface (14) of the flexographic printing element (16).

In a preferred embodiment, the flexographic printing element (16) is rotated in the first direction (30), while the roll (12) is rotated in a second direction (32). The flexographic printing element (16) is continuously rotated in the first direction (30) during both the exposing and developing steps so that the entire imaged surface (14) of the flexographic printing element (16) can be exposed and developed. The spiral nature of this process, wherein the printing sleeve rotates as the carriage (26) traverses the length of the flexographic printing element (16) ensures even exposure and development across any size printing element (16).

In another embodiment, as depicted in FIG. 5, the thermal development apparatus (10) of the invention further comprises a device (54) for detacking and post-curing the flexographic printing element (16) once the flexographic printing element (16) has been exposed with the one or more UV lights (52) and thermally developed with the at least one roll (12). The use of the detacking and post-curing device (54) in the apparatus (10″) of the invention eliminates the need for handling the printing element i.e., moving the printing element to a subsequent apparatus, and again provides for a more precise and accurate printing element.

The present invention is also directed to a method of removing non-crosslinked polymer from an imaged surface of the flexographic printing element with at least one roll. In a preferred embodiment, immediately prior to removal of the non-crosslinked polymer in a thermal developing step, the flexographic printing element is selectively exposed to actinic radiation to selectively crosslink and cure imaged portions of the flexographic printing element.

The method generally comprises the steps of:

a) supporting, and preferably rotating the flexographic printing element;

b) optionally, but preferably, exposing an imaged surface of the flexographic printing element to actinic radiation to crosslink and cure the imaged surface of the flexographic printing element;

c) melting or softening non-crosslinked polymer on the imaged and exposed surface of the flexographic printing element;

d) causing contact between the imaged surface of the flexographic printing element and a blotter using at least one roll; and

e) rotating the at least one roll against at least a portion of the imaged surface of the flexographic printing element to remove the softened or melted non-crosslinked photopolymer from the imaged surface of the flexographic printing element and transfer it to the blotter, wherein the blotter is colored in such a manner that the image created on the blotter by the transferred non-crosslinked photopolymer is not discernable by the unaided human eye.

The at least one roll may traverse the length of the cylindrical flexographic printing element in a spiral or stepwise manner. In a preferred embodiment, the at least one roll traverses the length of the flexographic printing element one or multiple times until all of the non-crosslinked polymer is removed from the imaged surface of the flexographic printing element. The roll may also be angled such that its axis of rotation is not parallel with the axis of rotation of the flexographic printing element, and can be transverse to the axis of rotation of the flexographic printing element.

In one embodiment, the non-crosslinked photopolymer on the imaged and exposed surface of the flexographic printing element is melted or softened by heating the at least one roll that contacts the imaged and exposed surface of the flexographic printing element.

In another embodiment, the non-crosslinked photopolymer on the imaged and exposed surface of the flexographic printing element is melted or softened by positioning a heater adjacent to the imaged and exposed surface of the flexographic printing element to soften or melt the non-crosslinked photopolymer for subsequent removal by the at least one roll. The heated roll and infrared heater may also be used together to facilitate additional removal of non-crosslinked photopolymer. If used, the at least one heated roll is typically maintained at a temperature that is between the melt temperature of the uncured photopolymer on the low end and the melt temperature of the cured photopolymer on the upper end. This will allow selective removal of the photopolymer thereby creating the image. Preferably the at least one heated roll is maintained at a temperature of about 350° F. to about 450° F.

As discussed above, in the preferred embodiment, the one or more sources of actinic radiation are one or more UV lights. If desired, the light source may include a filter to prevent undue heating of the printing element.

In another preferred embodiment, the method comprises a further step of detacking and post-curing the exposed and thermally developed printing element.

1. A method of developing a flexographic printing element which comprises cross-linked and non-crosslinked photopolymer, the method comprising the steps of:
a) supporting the flexographic printing element;
b) melting or softening non-crosslinked photopolymer on the flexographic printing element;
c) causing contact between the surface of the flexographic printing element and a blotter using at least one roll; and
d) rotating the at least one roll against at least a portion of the surface of the flexographic printing element to remove non-crosslinked photopolymer from the flexographic printing element and transfer the non-crosslinked photopolymer to the blotter; wherein the blotter is colored in such a manner that the image created on the blotter by the transferred non-crosslinked photopolymer is not discernable by the unaided human eye.

2. A method according to claim 1 wherein the blotter is a color selected from the group consisting of black, blue, brown and green.

3. A method according to claim 1 wherein the blotter is black.
